(19) United States
(12) Patent Application Publication
(10) Pub. No.: US 2014/0203363 A1
(43) Pub. Date: Jul. 24, 2014

(54) Extremely Thin Semiconductor-On-Insulator Field-Effect Transistor With An Epitaxial Source And Drain Having A Low External Resistance

(71) Applicant: International Business Machines Corporation, Armonk, NY (US)

(72) Inventors: Thomas N. Adam, Slingerlands, NY (US); Kevin K. Chan, Staten Island, NY (US); Kangguo Cheng, Schenectady, NY (US); Bruce B. Doris, Brewster, NY (US); Abhishek Dube, Fishkill, NY (US); Dechao Guo, Fishkill, NY (US); Ali Khakifirooz, Mountain View, CA (US); Ravikumar Ramachandran, Pleasantville, NY (US); Alexander Reznicek, Troy, NY (US)

(73) Assignee: International Business Machines Corporation, Armonk, NY (US)

(21) Appl. No.: 14/030,365

(22) Filed: Sep. 18, 2013

Related U.S. Application Data
(63) Continuation of application No. 13/746,940, filed on Jan. 22, 2013.

(51) Int. Cl. H01L 29/66; H01L 29/786

(52) U.S. Cl. CPC H01L 29/66742; H01L 29/786
USPC 257/347; 438/151

(57) ABSTRACT

An aspect of this invention is a method for fabricating an extremely thin semiconductor-on-insulator (ETSOI) field-effect transistor (FET) having an epitaxial source and drain. The method includes providing an ETSOI substrate; forming at least one isolation structure on the ETSOI substrate; forming a gate on the ETSOI substrate; forming a spacer on the ETSOI substrate; and using an epitaxial growth process to provide a raised source/drain structure having a non-uniform concentration of carbon along a vertical axis.

### CROSS-REFERENCE TO RELATED APPLICATION

This patent application is a continuation of copending U.S. patent application Ser. No. 13/746,940 filed on Jan. 22, 2013, the disclosure of which is incorporated herein by reference in its entirety.

### TECHNICAL FIELD

The exemplary embodiments of this invention relate generally to semiconductor devices and more particularly to structures and manufacturing methods for providing an extremely thin semiconductor-on-insulator (ETSOI) field-effect transistor (FET) having an epitaxial source and drain with a low external resistance.

### BACKGROUND

A common design objective is to decrease or minimize the required physical size of an integrated circuit. With the shrinking dimensions of various integrated circuit components, transistors such as FETs have experienced dramatic improvements in both performance and power consumption.

These improvements include reduced parasitic capacitance, reduced resistance, and increased current-carrying capacity. Nevertheless, the process of obtaining additional performance enhancements by further reducing the dimensions of integrated circuit components has recently encountered several technical limitations. When the process of downscaling is carried beyond a certain point, there is an increase in leakage current and device-to-device variability.

Planar transistors, such as metal oxide semiconductor field effect transistors (MOSFETs) are particularly well suited for use in high-density integrated circuits. As the size of MOSFETs and other devices decreases, the dimensions of source/drain regions, channel regions, and gate electrodes also decreases. The design of ever-smaller planar transistors with short channel lengths makes it necessary to provide very shallow source/drain junctions. Shallow junctions are necessary to avoid lateral diffusion of implanted dopants into the channel, since such diffusion disadvantageously contributes to leakage currents and poor breakdown performance. Shallow source/drain junctions, with a thickness of about 5 nm to 20 nm, are generally required for acceptable performance in short channel devices.

Silicon-on-insulator (SOI) technology allows the formation of high-speed, shallow junction devices. In addition, SOI devices improve performance by reducing parasitic junction capacitance. An SOI device is a device in which an oxide layer is formed on a substrate and subsequently buried below a thin semiconductor layer, thus resulting in a buried oxide (BOX) layer. A channel region is provided in the thin semiconductor layer between a gate dielectric and the BOX layer. The source and drain regions are formed on either side of the channel region in and/or above the thin semiconductor layer. When the source and drain regions are formed above the channel in whole or in part, they are referred to as raised source/drain (RSD) regions. The RSD regions may be fabricated by means of one or more extensions above the channel. In some device structures, for example, extremely thin SOI (ETSOI), the extension resistance becomes the dominant component of total external resistance. The extension resistance can be lowered by thickening the SOI in extension region as well. However, the trade-off has to be made between two competing requirements—lowering external resistance and minimizing the increase of parasitic capacitance.

The continued downscaling of SOI devices has resulted in a number of formerly unimportant parameters becoming significant circuit design factors. One example of such a design parameter is short-channel control. A MOSFET device is considered to be short when the channel length is the same order of magnitude as the depletion-layer widths of the source junction and drain junction. As the channel length is reduced to increase both the operational speed and the number of components per chip, the so-called short-channel effects arise. Short-channel effects refer to a set of undesired physical phenomena that may occur in the scaled down channel (reduced gate length) of a MOSFET. These effects may include drain-induced barrier lowering and punchthrough, surface scattering, velocity saturation, impact ionization, and hot carrier injection. These short-channel effects are attributed to two physical phenomena: the limitation imposed on carrier drift characteristics in the channel, and the modification of the threshold voltage due to the shortened channel length.

Extremely thin Silicon-On-Insulator (ETSOI) transistors are designed to overcome various shortcomings related to short channel effects. ETSOI is a fully depleted transistor device that uses an ultra-thin silicon channel wherein the channel is completely depleted of majority carriers in normal device operation. Since the channel is very thin, raised source/drain is needed to reduce the parasitic resistance of the transistor. In-situ doped epitaxial growth is used to provide raised source/drain (RSD) regions to boost ETSOI performance. Epitaxy is the growth of the crystals of one substance on the crystal face of another substance, such that the crystalline substrates of both substances have the same structural orientation. In-situ doped epitaxial layers are semiconductor layers such as Si, SiGe, Si:C, or SiGe:C, where dopant atoms such as phosphorus, arsenic, or boron are incorporated in the layer when the layer is epitaxially grown. This is done by adding carrier gases that contain dopant atoms in the gas mixture used to grow the epitaxial layer. Examples of such gases include phosphine, arsine, and borane.

The epitaxial growth of phosphorus doped Si:C (SiCP) to fabricate ETSOI devices is a process that involves a deposition followed by an etching followed by a further deposition. In many cases, this process may involve multiple cycles of deposition, etching, and further deposition. As the number of cycles of deposition, etching, and further deposition is increased, the extent of damage to a link-up region between the source/drain and the extension also increases. From an electrical standpoint, this damage causes an undesirable increase in external resistance of the ETSOI device.

In the case of an nFET semiconductor device, the use of in-situ phosphorous-doped Si without C lowers the on-resistance of the device. However, too much phosphorus diffusion may occur, resulting in poor observed short-channel effects. This issue may be addressed by using a lower drive-in temperature than that required for pFET drive-in. However, in the case of complementary metal oxide silicon (CMOS) transistors, it is desirable to have the same drive-in temperature for nFET devices as well as pFET devices. Drive-in refers to a high temperature (>800° C.) operation performed on a semiconductor wafer in an inert ambient environment. The operation causes motion and diffusion of dopant atoms in a semiconductor in the direction of the concentration gradient from areas of higher concentration into areas of lower concentration. Drive-in is used to drive the dopant atoms deeper into the semiconductor wafer.

It is possible to utilize in-situ phosphorus-doped Si:C instead of the previously described Si without C. Advantageously, the use of carbon addresses the problem of too much phosphorus diffusion. Carbon will slow down the diffusion process by reducing the density of interstitial point defects in Si, which are known to facilitate phosphorous diffusion. However, this does not occur without a significant tradeoff in the form of the carbon increasing silicide contact resistance.

### SUMMARY

In one aspect thereof the exemplary embodiments of this invention provide a method that includes fabricating an extremely thin semiconductor-on-insulator (ETSOI) field-effect transistor (FET) having an epitaxial source and drain, the method comprising providing an ETSOI substrate; forming at least one isolation structure on the ETSOI substrate; forming a gate on the ETSOI substrate; forming a spacer on the ETSOI substrate; and using an epitaxial growth process to provide a raised source/drain structure having a non-uniform concentration of carbon along a vertical axis.

In another aspect thereof, the exemplary embodiments provide a computer-readable memory that contains computer program instructions, where the execution of the computer program instructions by at least one data processor results in performance of operations that comprise fabricating an extremely thin semiconductor-on-insulator (ETSOI) field-effect transistor (FET) having an epitaxial source and drain, the method comprising providing an ETSOI substrate; forming at least one isolation structure on the ETSOI substrate; forming a gate on the ETSOI substrate; forming a spacer on the ETSOI substrate; and using an epitaxial growth process to provide a raised source/drain structure having a non-uniform concentration of carbon along a vertical axis.

In yet another aspect thereof, the exemplary embodiments provide a data processing system that comprises at least one data processor connected with at least one memory that stores computer program instructions for fabricating an extremely thin semiconductor-on-insulator (ETSOI) field-effect transistor (FET) having an epitaxial source and drain, the method comprising providing an ETSOI substrate; forming at least one isolation structure on the ETSOI substrate; forming a gate on the ETSOI substrate; forming a spacer on the ETSOI substrate; and using an epitaxial growth process to provide a raised source/drain structure having a non-uniform concentration of carbon along a vertical axis.

In yet another aspect thereof, the exemplary embodiments provide an extremely thin semiconductor-on-insulator (ETSOI) field-effect transistor (FET) having an epitaxial source and drain, the FET comprising an ETSOI substrate; at least one isolation structure on the ETSOI substrate; a gate on the ETSOI substrate; a spacer on the ETSOI substrate; and a raised source/drain structure having a non-uniform concentration of carbon along a vertical axis.

### BRIEF DESCRIPTION OF THE SEVERAL VIEWS OF THE DRAWINGS

FIG. 1A is a flowchart of a first exemplary method for fabricating an extremely thin semiconductor-on-insulator (ETSOI) field-effect transistor (FET) having an epitaxial source and drain.

FIG. 1B is a flowchart of a second exemplary method for fabricating an extremely thin semiconductor-on-insulator (ETSOI) field-effect transistor (FET) having an epitaxial source and drain.

FIG. 2 is a cross sectional view depicting a structure from which an extremely thin semiconductor-on-insulator (ETSOI) field-effect transistor (FET) is fabricated in accordance with an illustrative implementation of the method of FIG. IA.

FIG. 3 is a cross sectional view depicting the structure of FIG. 2 after an exemplary epitaxial growth process has been performed using a plurality of layers.

FIG. 4 is a cross sectional view depicting the structure of FIG. 2 after an exemplary epitaxial growth process has been performed using a single layer having a carbon gradient in the vertical dimension.

FIG. 5 is a cross sectional view depicting the structure of FIG. 4 after an exemplary drive-in annealing process has been performed.

FIG. 6 is a cross sectional view depicting the structure of FIG. 5 after an exemplary silicide layer has been formed.

FIG. 7 is a cross sectional view depicting the structure of FIG. 3 after an exemplary silicide layer has been formed.

FIG. 8 is a graph showing current in the off state (I_{off}) divided by design channel width (W_{des}) as a function of effective current (I_{eff}) divided by W_{des} for an N-channel ETSOI FET . . . .

### DETAILED DESCRIPTION

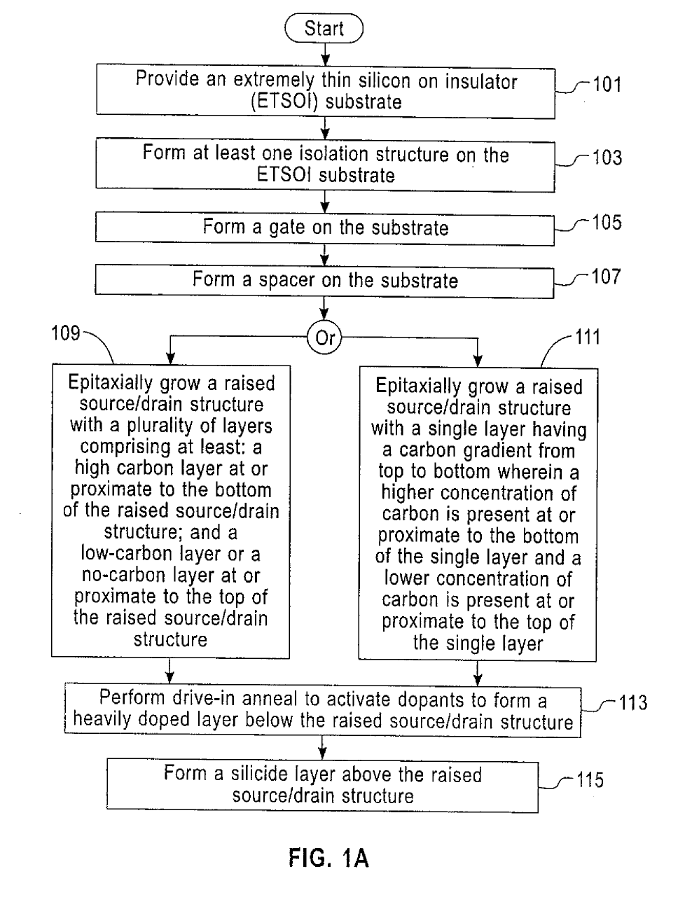

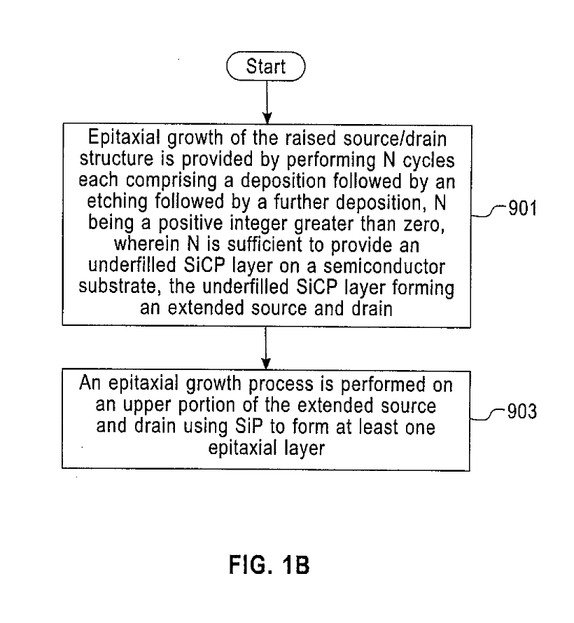

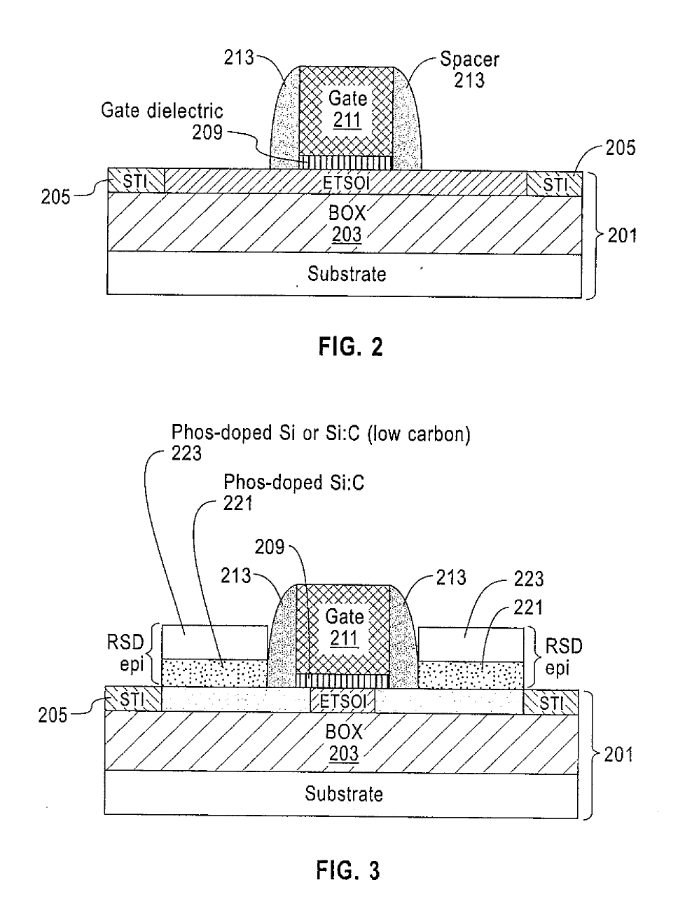

FIG. 1A is a flowchart of a first exemplary method for fabricating an extremely thin silicon-on-insulator (ETSOI) field-effect transistor (FET) having an epitaxial source and drain, and FIG. 2 is a cross sectional view depicting a structure from which an extremely thin semiconductor-on-insulator (ETSOI) field-effect transistor (FET) is fabricated in accordance with an illustrative implementation of the method of FIG. 1A. In overview, FIG. 1A sets forth exemplary methods for forming an ETSOI transistor with a raised source/drain structure having one or more layers each provided with in-situ dopants. A lower portion of an epitaxial layer is provided with a higher concentration of carbon relative to an upper portion of the epitaxial layer. The carbon gradient may be selected to slow down phosphorus (or other dopant) diffusion in the lower portion of the epitaxial layer during a dopant drive-in process that occurs at temperatures exceeding 800 degrees Celsius. The carbon gradient may be selected such that upper portion of the epitaxial layer contains low carbon or no carbon to achieve low suicide resistance to permit formation of ohmic contacts for the ETSOI transistor. In addition to, or in lieu of, a single epitaxial layer with a carbon gradient, a plurality of epitaxial layers may be provided comprising at least a lower epitaxial layer and an upper epitaxial layer, wherein the lower epitaxial layer has a higher concentration of carbon relative to the higher epitaxial layer.

An ETSOI substrate 201 (FIG. 2) is provided at block 101 (FIG. 1A). The ETSOI substrate 201 includes a buried oxide (BOX) layer 203. Next, at least one isolation structure is formed on the ETSOI substrate (block 103). For purposes of illustration, the isolation structure may be formed using any of shallow trench isolation (STI) 205 (FIG. 2), mesa, or local oxidation of silicon (LOCOS). In cases where the isolation structure is to be formed using STI 207, a thin pad oxide is grown on a silicon film. A layer of Silicon Nitride (Si₃N₄) is deposited. Photolithography and plasma etching are then used to pattern the nitride, pad oxide, and a silicon-on-insulator (SOI) layer. Chemical vapor deposition (CVD) is then used to deposit oxide or oxynitride and a chemical-mechanical polishing (CMP) is used to planarize the resulting structure. The nitride and pad oxide are then removed by a chemical etching process such as wet etching in hot phosphoric acid and HF, respectively.

If the isolation structure is to be formed using a mesa, the ETSOI substrate 201 is patterned into one or more islands or mesas using a mask step and a silicon etching step. Passivation of the island or mesa edges is performed using a gate oxidation step where the gate dielectric is grown not only on top of the islands but on their edges as well.

The isolation structure may be provided using a LOCOS process. Illustratively, LOCOS can be employed to fabricate semiconductor devices such as complementary metal-oxide silicon (CMOS) or metal-oxide silicon (MOS) transistors. The LOCOS process is implemented by forming Silicon Dioxide (SiO₂) in selected areas on the ETSOI substrate 201 to provide an insulating structure that penetrates under the surface of the substrate 201 such that the resulting Si—SiO₂ interface occurs below the upper Si surface of the ETSOI substrate. In this manner, a thick pad of thermally grown SiO₂ can be used to separate adjacent devices. Local oxidation is accomplished by using Silicon Nitride (Si₃N₄) to prevent oxidation of Si in selected areas. Silicon oxide is then formed using thermal oxidation of selected regions surrounding transistors. The oxygen penetrates into the depth of the substrate 201, reacts with silicon and transforms it into silicon dioxide. In this way, an immersed structure is formed.

After at least one isolation structure is formed on the ETSOI substrate 201 (see also block 103, FIG. 1A), a gate structure is formed on the ETSOI substrate (block 105) comprising a gate dielectric 209 (FIG. 2) and a gate 211. This gate structure comprises a real or actual gate if a gate-first fabrication technique is employed. Alternatively, if a gate-last fabrication technique is employed, this gate structure is the dummy gate. Next, at block 107 (FIG. 1A), a spacer 213 (FIG. 2) is formed on the substrate 201. Illustratively, block 107 (FIG. 1A) may be performed using deposition of Silicon Nitride (Si₃N₄) and reactive ion etching (RIE).

After block 107 is performed, the procedure of FIG. 1A progresses to either block 109 or block 111. At block 109, a multi-layer raised source/drain structure is grown epitaxially. FIG. 3 is a cross sectional view depicting the structure of FIG. 2 after an exemplary epitaxial growth process has been performed using a plurality of layers. The raised source/drain structure includes at least a high-carbon layer 221 (FIG. 3) at or proximate to the bottom of the raised source/drain structure, and a low-carbon or no-carbon layer 223 at or proximate to the top of the raised source/drain structure. The high-carbon layer 221 may be fabricated using phosphorus-doped Si:C, for example Si:C with carbon concentration of 1% or more. The low-carbon or no-carbon layer 223 may be fabricated using phosphorus-doped Si or phosphorus-doped, low-carbon Si:C, for example Si:C with carbon concentration less than about 0.5%.

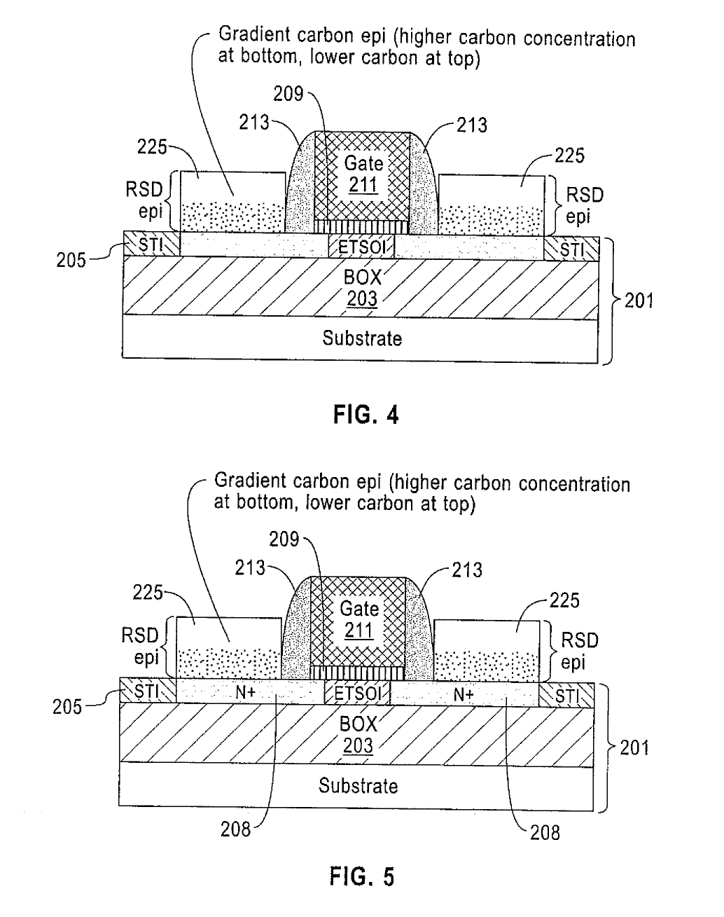

From block 107, the procedure of FIG. 1A may progress to block 111 where a single-layer raised source/drain structure is grown epitaxially. FIG. 4 is a cross sectional view depicting the structure of FIG. 2 after an exemplary epitaxial growth process has been performed using a single layer 225 (FIG. 4) having a carbon gradient in the vertical dimension. The single layer 225 includes a high-carbon portion at or proximate to the bottom of the raised source/drain structure, and a low-carbon or no-carbon portion at or proximate to the top of the raised source/drain structure. Illustratively, the layer 225 may be fabricated using phosphorus-doped Si:C, phosphorus-doped Si, phosphorus-doped, low-carbon Si:C, or any of various combinations thereof.

From block 109 or block 111, the procedure of FIG. 1A progresses to block 113 where a drive-in annealing process is performed to activate one or more dopants to form a heavily doped layer below the raised source/drain structure. FIG. 5 is a cross sectional view depicting the structure of FIG. 4 after an exemplary drive-in annealing process has been performed. In the illustrative example of FIG. 5, the annealing process is used to provide an N+ doped source/drain region 208 below the layer 225. However, it is possible to provide a P+ doped source/drain region instead of the N+ doped source/drain region in accordance with a specific semiconductor device to be fabricated.

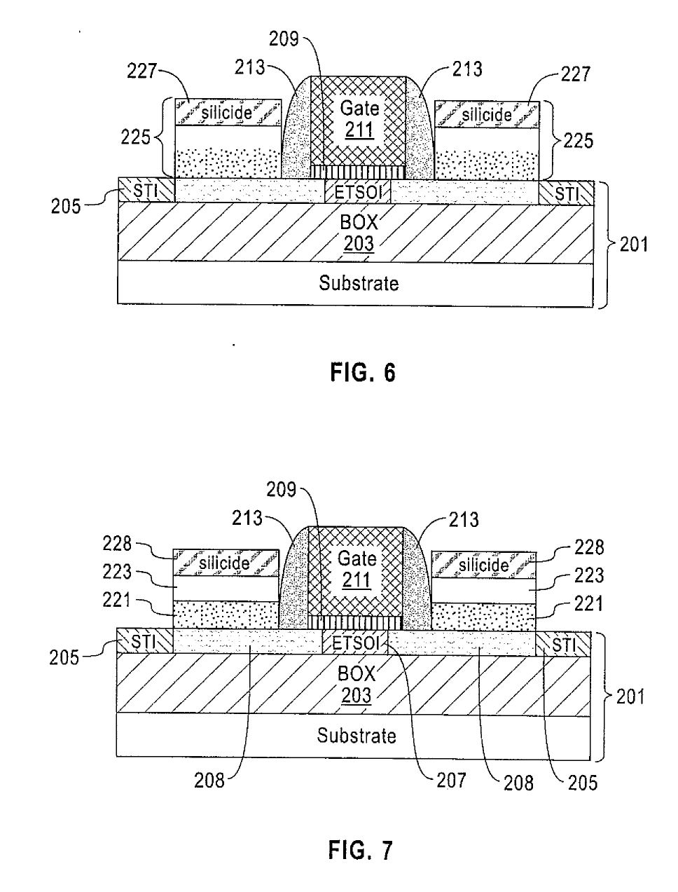

The procedure of FIG. 1A progresses to block 115 where a silicide layer is formed above the raised source/drain structure. For example, FIG. 6 is a cross sectional view depicting the structure of FIG. 5 after a silicide layer 227 has been formed. Similarly, FIG. 7 is a cross sectional view depicting the structure of FIG. 3 after an exemplary silicide layer 228 has been formed.

A silicide is a compound that contains silicon with at least one element that is more electropositive than silicon. Illustrative examples of suitable electropositive elements include but are not limited to Ni, Pt, Pd, Ti, Co, W, Yt, and Nb. The chemical bonds in silicides range from conductive metal-like structures to covalent bonds or ionic bonds. Silicides of any non-transition metal, with exception of beryllium, may be used. Mercury, thallium, bismuth, and lead are nonmiscible with liquid silicon and are not generally used to provide silicides. Silicon atoms in silicides can have many possible organizations: (1) Isolated silicon atoms: electrically conductive Cu₅Si, (V, Cr, Mn)₃Si, Fe₃Si, Mn₃Si, and nonconductive (Mg, Ge, Sn, Pb)₂Si, (Ca, Ru, Ce, Rh, Ir, Ni)₂Si; (2) Siₜ pairs such as U₃Si₂, Hf and Th; (3) Si₄ tetrahedra: KSi, RbSi, CsSi; (4) Siₙ chains: USi, (Ti, Zr, Hf, Th, Ce, Pu)Si, CaSi, SrSi, Ysi; (5) planar hexagonal graphite-like Si layers: β-usi₂, silicides of other lanthanoids and actinoids; (6) corrugated hexagonal Si layers: CaSi₂; or (7) open three-dimensional Si skeletons: SrSi₂, ThSi₂, α-USi₂.

A silicide prepared by a self-aligned process is called a salicide. This is a process in which silicide contacts are formed only in those areas in which deposited metal (which after annealing becomes a metal component of the silicide) is in direct contact with silicon, hence, the process is self-aligned. This process may be implemented to provide ohmic contacts for the source, drain, and poly-Si gate of a transistor.

FIG. 1B is a flowchart of an exemplary method for implementing the procedure of at least one of block 109 or block 111 of FIG. 1A. The procedure commences at block 901 where epitaxial growth of the raised source/drain structure is provided by performing N cycles each comprising a deposition followed by an etching followed by a further deposition, N being a positive integer greater than zero, wherein N is sufficient to provide an underfilled SiCP layer on a semiconductor substrate, the underfilled SiCP layer forming an extended source and drain. Next, at block 903, an epitaxial growth process is performed on an upper portion of the extended source and drain using SiP to form at least one epitaxial layer.

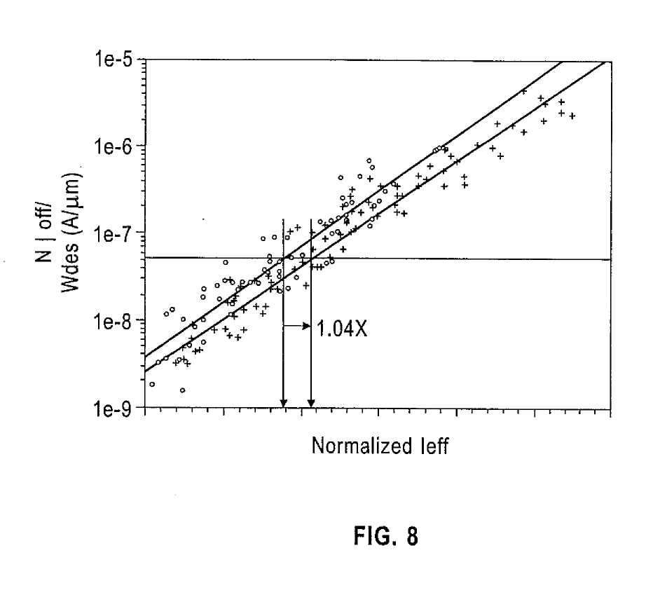

Illustratively, the raised source/drain structure of FIG. 7 is a bi-layer epitaxial structure that includes a high-carbon layer 221 at or proximate to the bottom of the raised source/drain structure, and a low-carbon or no-carbon layer 223 at or proximate to the top of the raised source/drain structure. By comparison, the raised source/drain structure of FIG. 6 is a single layer 225 epitaxial structure having a carbon gradient in the vertical dimension. The single layer 225 includes a high-carbon portion at or proximate to the bottom of the raised source/drain structure, and a low-carbon or no-carbon portion at or proximate to the top of the raised source/drain structure. FIG. 8 is a normalized graph showing current in the off state (I_{off}) divided by design channel width (W_{des}) as a function of effective current (I_{eff}) divided by W_{des} for an N-channel ETSOI FET. This graph was prepared using an epitaxial bi-layer structure similar to that shown in FIGS. 3 and 7. Using an epitaxial bi-layer structure with a SiP cap 223 (FIG. 7) provides approximately 4% I_{eff} gain.

As should be appreciated by one skilled in the art, aspects of the present invention may be embodied as a method, a computer-readable memory, a data processing system, a semiconductor device, or as a combination of these. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit”, “device”, “module” or “system”. Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document a computer readable storage medium may be any tangible, non-transitory medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the computer, partly on the computer, as a stand-alone software package, partly on the computer and partly on a remote computer or entirely on the remote computer or server. In the latter scenario, the remote computer may be connected to the computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, devices, apparatuses, systems and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowcharts and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

As such, various modifications and adaptations may become apparent to those skilled in the relevant arts in view of the foregoing description, when read in conjunction with the accompanying drawings and the appended claims. As but some examples, the use of other similar or equivalent mathematical expressions may be used by those skilled in the art. However, all such and similar modifications of the teachings of this invention will still fall within the scope of this invention.

What is claimed is:

1. A computer-readable memory that contains computer program instructions, where the execution of the computer program instructions by at least one data processor results in performance of operations that comprise fabricating an extremely thin semiconductor-on-insulator (ETSOI) field-effect transistor (FET) having an epitaxial source and drain by:
providing an ETSOI substrate;
forming at least one isolation structure on the ETSOI substrate;
forming a gate on the ETSOI substrate;
forming a spacer on the ETSOI substrate; and
using an epitaxial growth process to provide a raised source/drain structure having a non-uniform concentration of carbon.

2. The computer-readable memory of claim 1 further comprising instructions for performing the epitaxial growth process by:
performing N cycles each comprising a deposition followed by an etching followed by a further deposition, N being a positive integer greater than zero, wherein N is sufficient to provide an underfilled SiCP layer on a semiconductor substrate, the underfilled SiCP layer forming an extended source and drain.

3. The computer-readable memory of claim 2 further comprising instructions for performing the epitaxial growth process by performing epitaxial growth on an upper portion of the extended source and drain using SiP to form at least one epitaxial layer.

4. The computer-readable memory of claim 1 further comprising computer program instructions for providing a single epitaxial layer having a bottom portion, a top portion and a carbon gradient such that the bottom portion is provided with a higher concentration of carbon relative to the top portion.

5. The computer-readable memory of claim 1 further comprising computer program instructions for providing a first epitaxial layer and a second epitaxial layer, the first epitaxial layer being above the second epitaxial layer, the first epitaxial layer having a first concentration of carbon and the second epitaxial layer having a second concentration of carbon, wherein the second concentration of carbon is greater than the first concentration of carbon.

6. The computer-readable memory of claim 4 further comprising computer program instructions for selecting the carbon gradient to slow down phosphorus diffusion in the lower portion of the epitaxial layer during a dopant drive-in process.

7. The computer-readable memory of claim 6 wherein the dopant drive-in process occurs at temperatures exceeding 800 degrees Celsius.

8. The computer-readable memory of claim 4 further comprising computer program instructions for selecting the carbon gradient such that upper portion of the epitaxial layer contains low carbon or no carbon to achieve low silicide resistance to permit formation of ohmic contacts to the raised source/drain structure of the ETSOI FET.

9. The computer-readable memory of claim 5 further comprising computer program instructions for selecting the second concentration of carbon to slow down phosphorus diffusion in the second epitaxial layer during a dopant drive-in process that occurs at temperatures exceeding 800 degrees Celsius.

10. The computer-readable memory of claim 5 further comprising computer program instructions for selecting the first concentration of carbon to achieve low silicide resistance of the first epitaxial layer to permit formation of ohmic contacts to the raised source/drain structure of the ETSOI FET.

11. A data processing system that comprises at least one data processor connected with at least one memory that stores computer program instructions for fabricating an extremely thin semiconductor-on-insulator (ETSOI) field-effect transistor (FET) having an epitaxial source and drain by:
providing an ETSOI substrate;
forming at least one isolation structure on the ETSOI substrate;
forming a gate on the ETSOI substrate;
forming a spacer on the ETSOI substrate; and
using an epitaxial growth process to provide a raised source/drain structure having a non-uniform concentration of carbon.

12. The data processing system of claim 11 further comprising computer program instructions for performing the epitaxial growth process by providing a single epitaxial layer having a bottom portion, a top portion and a carbon gradient such that the bottom portion is provided with a higher concentration of carbon relative to the top portion.

13. An extremely thin semiconductor-on-insulator (ETSOI) field-effect transistor (FET) having an epitaxial source and drain, the FET comprising:
an ETSOI substrate;
at least one isolation structure on the ETSOI substrate;
a gate on the ETSOI substrate; a spacer on the ETSOI substrate; and
a raised source/drain structure having a non-uniform concentration of carbon along a vertical axis.

14. The ETSOI FET of claim 13 wherein the raised source/drain structure comprises a single epitaxial layer having a bottom portion, a top portion and a carbon gradient such that the bottom portion is provided with a higher concentration of carbon relative to the top portion.

15. The ETSOI FET of claim 13 wherein the raised source/drain structure comprises a first epitaxial layer and a second epitaxial layer, the first epitaxial layer being above the second epitaxial layer, the first epitaxial layer having a first concentration of carbon and the second epitaxial layer having a second concentration of carbon, wherein the second concentration of carbon is greater than the first concentration of carbon.

16. The ETSOI FET of claim 14 wherein the carbon gradient has a concentration of carbon in at least a portion of the lower portion of the epitaxial layer, the concentration known to slow down phosphorus diffusion during a dopant drive-in process.

17. The ETSOI FET of claim 16 wherein the dopant drive-in process occurs at temperatures exceeding 800 degrees Celsius.

18. The ETSOI FET of claim 14 wherein the carbon gradient is selected such that upper portion of the epitaxial layer contains low carbon or no carbon to achieve low silicide resistance to permit formation of ohmic contacts to the raised source/drain structure of the ETSOI FET.

19. The ETSOI FET of claim 15 wherein the second concentration of carbon has a concentration of carbon causing phosphorus diffusion to slow down in the second epitaxial layer during a dopant drive-in process that occurs at temperatures exceeding 800 degrees Celsius.

20. The ETSOI FET of claim 15 wherein the first concentration of carbon has a concentration of carbon causing low silicide resistance of the first epitaxial layer to permit formation of ohmic contacts to the raised source/drain structure of the ETSOI FET.
